(19) United States
(12) Patent Application Publication
(10) Pub. No.: US 2026/0268800 A1
(43) Pub. Date: Sep. 10, 2026

(54) Three-Dimensionally Printed Strain Gauges Applied To Three-Dimensionally Printed Components Of A Crash Test Dummy And Associated Methods For Producing Same

(71) Applicant: Humanetics Innovative Solutions, Inc., Farmington Hills, MI (US)

(72) Inventors: Michael Scott Beebe, Norwalk, OH (US); Paul Joseph Depinet, Norwalk, OH (US); Kristopher H. Sullenberger, Sandusky, OH (US)

(73) Assignee: Humanetics Innovative Solutions, Inc., Farmington Hills, MI (US)

(21) Appl. No.: 19/163,712

(22) PCT Filed: Mar. 18, 2024
(86) PCT No.: PCT/US2024/020395

§ 371 Date: Sep. 9, 2025

Related U.S. Application Data
(60) Provisional application No. 63/490,710, filed on Mar. 16, 2023.

(51) Int. Cl. G09B 23/30; B33Y 10/00; B33Y 50/00; B33Y 80/00; G01L 1/22; G06F 30/13

(52) U.S. Cl. CPC G09B 23/30; B33Y 50/00; B33Y 80/00; G01L 1/2287; G06F 30/13; B33Y 10/00

(57) ABSTRACT

A strain gauge applied to a component used in a crash test dummy is used to evaluate the performance of the component during a crash test simulation. The strain gauge may be directly applied onto the outer surface of the component using three-dimensional printing or may be applied to a polymeric sheet having an adhesive backing which is subsequently applied to the outer surface of the component. The strain gauge may then be electrically coupled to a controller through a wiring harness to measure a change in electrical signed of the strain gauge corresponding to a change in strain of the rib occurring during a crash test simulation in a time span from 10 to 200 milliseconds.

### CROSS-REFERENCE TO RELATED APPLICATIONS

The present application claims priority to and all the benefits of U.S. Provisional Patent Application No. 63/490,710, filed on Mar. 16, 2023, the entire contents of which are expressly incorporated herein by reference.

### BACKGROUND OF THE INVENTION

### 1. Field of the Invention

The subject disclosure relates generally to crash test dummies and, more particularly, to three-dimensionally printed strain gauges and a method of three-dimensional printing of strain gauges directly or indirectly onto three-dimensionally printed components for a crash test dummy.

### 2. Description of the Related Art

Automotive, aviation, and other vehicle manufacturers conduct a wide variety of collision testing to measure the effects of a collision on a vehicle and its occupants. Through collision testing, a vehicle manufacturer gains valuable information that can be used to improve the vehicle, authorities examine vehicles to submit type approval, and consumer organizations provide information on vehicle safety ratings to the public.

Collision testing often involves the use of anthropomorphic test devices, better known as “crash test dummies”, to estimate a human's injury risk. The dummy must possess the general mechanical properties, dimensions, masses, joints, and joint stiffness of the humans of interest. In addition, they must possess sufficient mechanical impact response similitude and sensitivity to cause them to interact with the vehicle's interior in a human-like manner. Such collision impacts are typically done in a short time span, such as between 10 and 200 milliseconds, and impart a large amount of force on a given component of the crash dummy, such as greater than 3500 or 7000 N.

The subject disclosure relates to the inclusion of assessment tools coupled to the components of the crash test dummy that allow for improved evaluation of such components during and after crash test simulations.

### SUMMARY OF THE INVENTION

The subject disclosure provides a three-dimensionally printed strain gauge for use on three-dimensionally printed components of a crash test dummy, and an associated method for application of the three-dimensionally printed strain gauge directly or indirectly onto three-dimensionally printed components of the crash test dummy to define an integrated sensor on the three-dimensionally printed component where the three-dimensionally printed component undergoes a sudden impact causing strain in the integrated sensor in a very short time span (i.e., the time of an impact simulation), such as within a time span of from 10 to 200 milliseconds.

In certain embodiments, the three-dimensionally printed component is a three-dimensionally printed rib, such as a three-dimensionally printed rib included as a part of a rib cage assembly for the crash test dummy.

In certain embodiments, the three-dimensionally printed strain gauge is printed directly onto an outer surface of the three-dimensionally printed component, such as the three-dimensionally printed rib.

In certain other embodiments, the three-dimensionally printed strain gauge is printed onto a first side of a polymeric sheet, which is subsequently coupled onto an outer surface of the three-dimensionally printed component such that the polymeric sheet is disposed between the three-dimensionally printed component and the three-dimensionally printed strain gauge. In certain of these embodiments, an adhesive backing is applied onto an opposing second side of the polymeric sheet, with the adhesive of the adhesive backing used to adhere the polymeric sheet to the outer surface of the three-dimensionally printed component.

The three-dimensionally printed strain gauges may then be electrically coupled to a controller unit through a wire of a wiring harness, which is electrically coupled to ends of the strain gauge via a solder joint. Once electrically coupled, the three-dimensionally printed component is available for use in a crash test dummy for one, or repeated, crash test simulations, with the three-dimensionally printed component shaped and sized to simulate how the corresponding component on a human would perform under the same crash test conditions.

Other features and advantages of the subject disclosure will be readily appreciated, as the same becomes better understood, after reading the subsequent description taken in conjunction with the accompanying drawings.

### BRIEF DESCRIPTION OF THE DRAWINGS

FIG. 1 is a perspective view of one embodiment of a rib cage assembly, prior to the inclusion of the three-dimensionally printed strain gauge thereon, illustrated in operational relationship with a crash test dummy.

FIG. 2 is a side view of the rib cage assembly illustrated in operational relationship with the crash test dummy of FIG. 1.

FIG. 3 is a top view of one embodiment of a three-dimensionally printed rib for the rib cage assembly of FIGS. 1 and 2 prior to the introduction of one or more three-dimensionally printed strain gauges.

FIG. 4 is a side view of the three-dimensionally printed rib of FIG. 3.

FIG. 5 is a schematic view of one embodiment of a three-dimensional printing system for printing the three-dimensionally printed rib of FIGS. 3-4.

FIG. 6 is a flowchart of a method, according to the subject disclosure, for three-dimensional printing of the three-dimensionally printed ribs of FIGS. 3-4.

FIG. 7 is a perspective view of a three-dimensionally printed rib for use in the crash test dummy of FIG. 1 according to an alternative embodiment that includes a pair of three-dimensionally printed strain gauges formed thereon.

FIG. 8 is a perspective view of a three-dimensionally printed half-rib for use in the crash test dummy of FIG. 1 according to an alternative embodiment prior to the introduction of one or more three-dimensionally printed strain gauges.

FIG. 9 is a perspective view of a three-dimensionally printed half-rib of FIG. 8 after the introduction of a plurality of three-dimensionally printed strain gauges formed thereon.

FIG. 10 is a perspective view of an alternative embodiment of the three-dimensionally printed rib of FIG. 8 including a plurality of three-dimensionally printed strain gauges formed thereon.

FIG. 11 is another perspective view of three-dimensionally printed half rib having a pair of three-dimensionally printed strain gauges formed with one of the three-dimensionally printed strain gauges electrically connected to a controller via a wiring harness.

FIG. 12 is another perspective view of a three-dimensionally printed full rib having a three-dimensionally printed strain gauge printed on a polymeric film with the polymeric film coupled to the outer surface of the rib and with the strain gauge electrically connected to a controller via a wiring harness.

FIG. 13 is a flowchart of a method, according to the subject disclosure, building upon method of FIG. 6 to further include the steps coupling the electrical componentry of a wiring harness and a controller to the strain gauge.

FIG. 14 is a flowchart of a method, according to the subject disclosure, for evaluating the formed modified rib of FIG. 13 in one or more crash test simulations.

### DESCRIPTION OF THE PREFERRED EMBODIMENT(S)

The subject application is directed to the introduction of a three-dimensionally printed strain gauge (the term “gauge” as in “strain gauge” may alternatively be spelled “gage” and is therefore the equivalent to the term “strain gage” and may be used interchangeably herein) on one or more three-dimensionally printed components of a crash test dummy. For ease of description, and in accordance with the exemplary embodiments provided below, the three-dimensionally printed strain gauge is described in connection with its use on one or more three-dimensionally printed ribs of the rib cage assembly of the crash test dummy. However, it is contemplated that the three-dimensionally printed strain gauge described below may be alternatively used on any other three-dimensionally printed component of the crash test dummy in the same manner as on one of the three-dimensionally printed rib of the rib cage assembly of the crash test dummy.

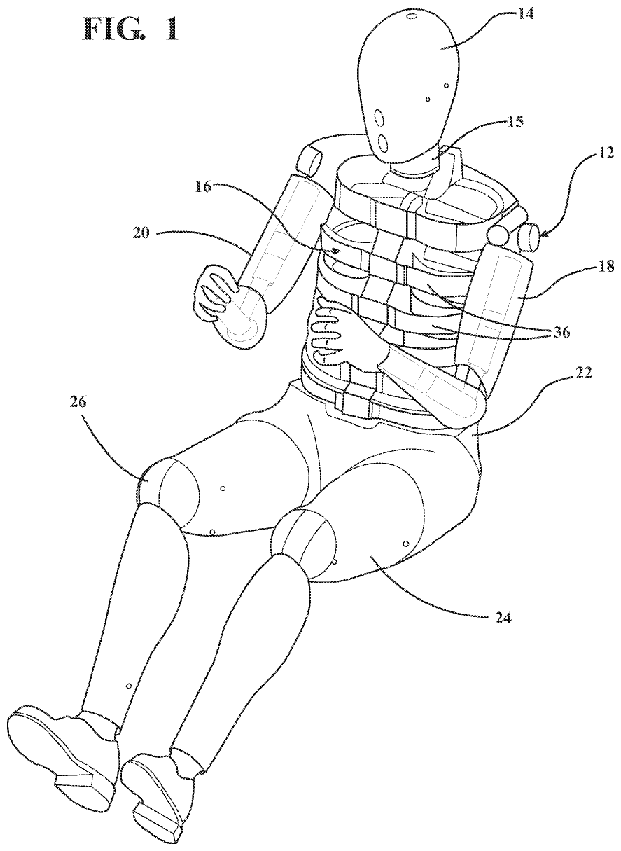

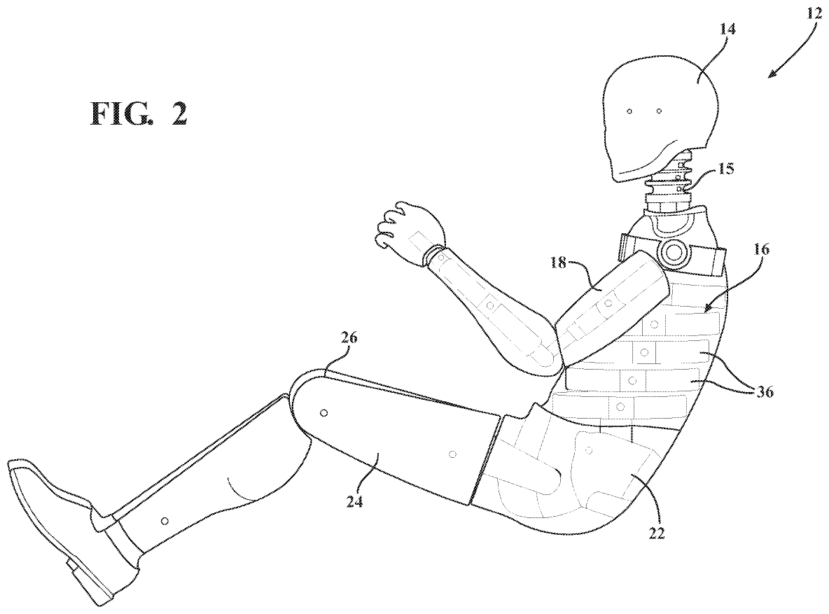

Referring to the drawings and in particular FIGS. 1 and 2, one embodiment of a crash test dummy, is generally indicated at 12. The crash test dummy 12 is of a fifth percentile (5%) female type and is illustrated in a sitting position. This crash test dummy 12 is used primarily to evaluate the performance of automotive interiors and restraint systems for adult front and rear seat occupants. The size and weight of the crash test dummy 12 are based on anthropometric studies, which are typically done separately by the following organizations, University of Michigan Transportation Research Institute (UMTRI), U.S. Military Anthropometry Survey (ANSUR), and Civilian American and European Surface Anthropometry Resource (CESAR). It should be appreciated that ranges of motions, centers of gravity, and segment masses simulate those of human subjects defined by the anthropometric data.

As illustrated in FIGS. 1 and 2, the crash test dummy 12 includes a head assembly 14, which includes a one-piece plastic skull, an instrumentation core, and a vinyl skin. The instrumentation core is removable for access to head instrumentation contained inside the head assembly 14.

The crash test dummy 12 also includes a spine assembly 15 having an upper end mounted to the head assembly 14 by a nodding block (not shown) and a nodding joint (not shown). The spine assembly 15 has a lower end extending into a torso area of the crash test dummy 12 and is connected to a spine mounting weldment (not shown) by an adapter assembly (not shown).

The crash test dummy 12 includes a torso or rib cage assembly 16 connected to the spine assembly 15. The spine assembly 15 also includes a neck (not shown) connected to the head assembly 14 and a spine box (not shown) connected to the neck. The neck has a lower end connected to by a suitable attachment such as one or more fasteners (not shown) to the spine box. It should be appreciated that the fasteners threadably engage apertures (not shown) in the spine box to secure the neck to the spine box. The crash test dummy 12 also has a pair of arm assemblies including a right arm assembly 18 and a left arm assembly 20, which are attached to the crash test dummy 12. The left arm assembly 20 includes a clavicle link (not shown), which connects a clavicle (not shown) to the top of the spine assembly 15. It should be appreciated that the right arm assembly 18 is constructed in an equivalent manner.

As illustrated in the FIGS. 1 and 2, a lower end of the lumbar spine is connected to a lumbar-thoracic adapter (not shown), which is connected to a lumbar to pelvic adapter (not shown). The crash test dummy 12 includes a pelvis assembly 22 connected to the adapter. The crash test dummy 12 also includes a right leg assembly 24 and a left leg assembly 26, which are attached to the pelvis assembly 22. It should be appreciated that various components of the crash test dummy 12 are covered in a urethane skin such as a flesh and skin assembly (not shown) for improved coupling with the skeleton of the crash test dummy 12. It should also be appreciated that a lifting ring (not shown) may be attached to the head assembly 14 for lifting the crash test dummy 12 into and out of test fixtures and vehicles.

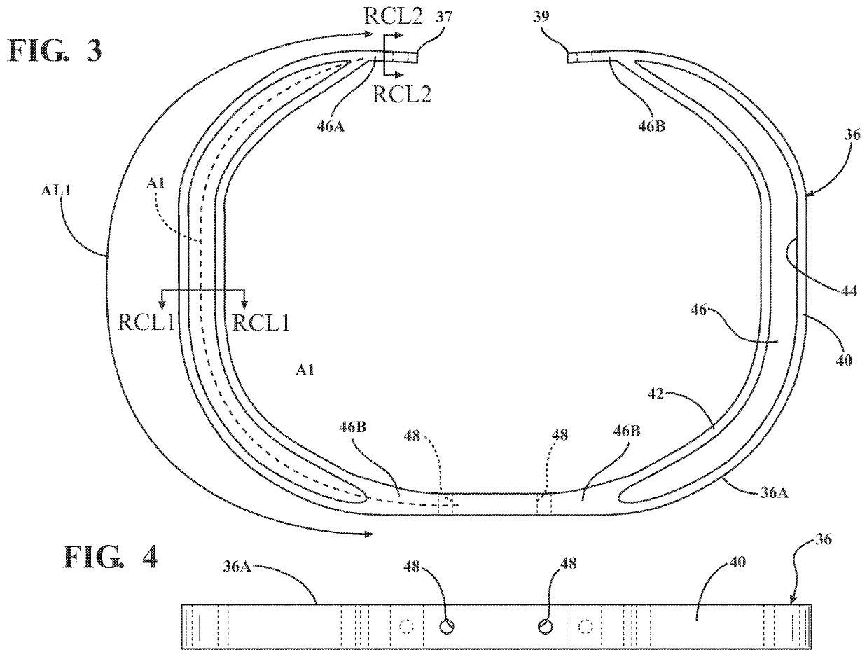

Referring to FIGS. 1 and 2, the rib cage assembly 16 includes one or more ribs 36. The ribs 36 extend between the spine box and a sternum 34. As illustrated in one embodiment in FIGS. 3 and 4 for a rib #3, the ribs 36 are generally arcuate and rectangular in shape but may be any suitable shape. The ribs 36 are vertically spaced along the spine box and sternum 34. The ribs 36 are connected to the spine box and sternum 34 by a suitable mechanism such as fasteners (not shown).

Each of the ribs 36 has a general “C” shape that extends in length AL (i.e., an arcuate length AL) between a pair of opposing ends 37, 39. In certain embodiments, such as in FIG. 3 and FIG. 7 and FIG. 12, the ribs 36 are full ribs 36A having the “C” shape described, whereas in other embodiments the ribs 36 are half ribs 36B (see FIGS. 8-11), corresponding to a right rib 36B and left rib 36B that are each separately connected to the spine box. Unless otherwise specifically stated to the contrary, the description of a rib 36 specifically encompasses the description of a full rib 26A or a half rib 36B.

In the exemplary embodiments provided herein, each rib 36 preferably includes at least two band layers. In one embodiment, each rib 36 has a front band layer 40 (i.e., first band layer 40) and a rear band layer 42 (i.e., second band layer 42) with an interior 44 spaced therebetween. The front band layer 40 and rear band layer 42 are made of a band material. Each layer 40 and 42 has a thickness from approximately 2.0 millimeters to approximately 6.0 millimeters, preferably approximately 4.0 millimeters. As illustrated in FIG. 3, each rib 36 preferably includes a layer of damping material 46 (i.e., a damping layer 46) disposed or sandwiched in between the two band layers 42 and 44, although in other embodiments the damping layer 46 may be omitted (see FIGS. 8-11). The damping layer 46, when present, has a thickness from approximately 8.0 millimeters to approximately 10.0 millimeters, preferably approximately 9.5 millimeters. Each rib 36 includes at least one, preferably a plurality of apertures 48 to allow fasteners (not shown) to extend therethrough for connection of the rib cage assembly 16 to the crash test dummy 12.

In certain embodiments, as best shown in FIG. 3, the rib 36 forms a first rectangular cross-section RCL1 comprising the damping layer 46 sandwiched between the two band layers 40, 42 that extends along an axis A1 perpendicular to the first rectangular cross-section RCL1 to form an arcuate sublength AL1 terminated at opposing ends 46A, 46B. Each of the opposing ends 46A, 46B forms a second rectangular cross-section RCL2 comprising the unitary band layer 40 and 42 without the damping layer 46 that extends away from the adjoined first rectangular cross-section damping layer 46 along the axis A1.

As will be described herein, in certain embodiments, the ribs 36 are formed using a three-dimensional printing process. The printable materials for the rib 36 are commercially available from Markforged of Watertown, Massachusetts sold under the commercial name Markforged Onyx, which is a nylon material that includes carbon fiber. It should also be appreciated that the dimensions and thicknesses of the ribs 36 will vary depending on the crash test dummy. It should also be appreciated that this process could be applied to other rib designs as well, for example, bigger, smaller, and different shapes.

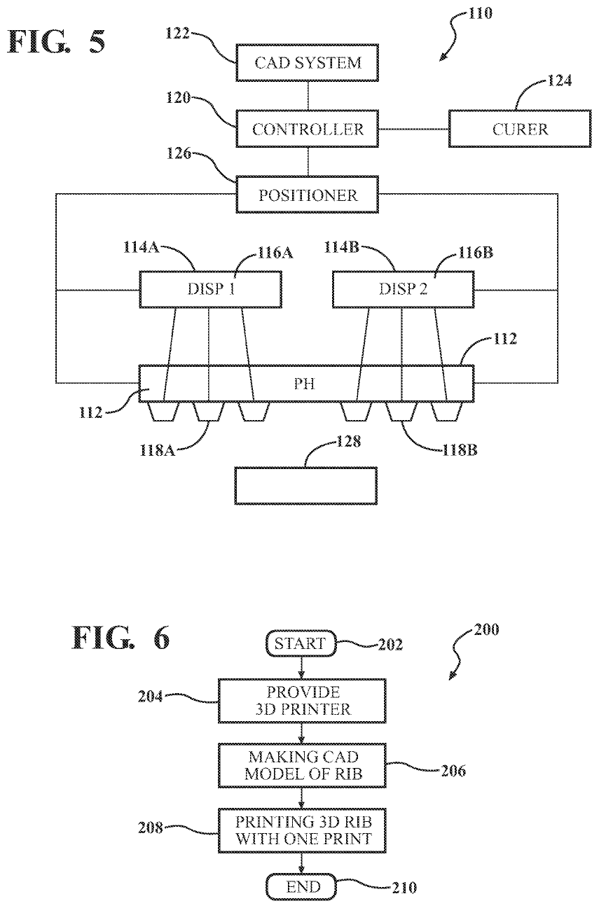

Referring to FIG. 5, a three-dimensional printer or printing system, generally designated 110, includes one or more printing heads 112, and at least two dispensers 114 and individually referenced 114A and 114A, containing printable materials, generally referenced 116 and individually referenced 116A and 116B, respectively. It should be appreciated that other components, and other sets of components, may be used.

The printing head 112 has a plurality of ink-jet type nozzles 118, through which printable materials 116A and 116A are jetted. In one embodiment, the first dispenser 114A is connected to a first set of nozzles 118A, and second dispenser 114B is connected to a second set of nozzles 118B. Thus, first printable material 116A is jetted through the nozzles 118A, and the second printable material 116B is jetted through nozzles 118B. In another embodiment (not shown), the three-dimensional printing system 110 may include at least two printing heads 112. The first printing head 112 is connected to first dispenser 114A and is used to jet first printable material 116A; and the second printing head 112 is connected to second dispenser 114B is used to jet second printable material 116B.

The three-dimensional printing system 110 further includes a controller 115, a Computer Aided Design (CAD) system 122, a curing unit 124, and optionally a positioning apparatus 126. The controller 115 is coupled to the CAD system 122, curing unit 124, positioning apparatus 126, printing head 112 and each of the dispensers 114. It should be appreciated that control may be effected by other units than shown, such as one or more separate units.

One exemplary three-dimensional printing system 110 used to form the ribs 36 in accordance with the subject disclosure is the Markforged Printer, commercially available from Markforged of Watertown, Massachusetts.

The three-dimensionally printed rib 36 is built in layers, the depth of each layer typically being controllable by selectively adjusting the output from each of the ink-jet type nozzles 118.

By combining or mixing materials from each of the dispensers 114, wherein each dispenser 114 contains printable material having a different hardness, it is possible to adjust and control the hardness of the material forming the three-dimensionally printed rib 36 being produced. Thus, by combining the first and second interface materials being output from each of the dispensers 114, respectively, distinct parts of the three-dimensionally printed rib 36 having a different modulus of elasticity and a different strength may be produced. It should be appreciated that such a three-dimensional printing system is disclosed in U.S. Pat. No. 8,481,241 to Napadensky et al., the entire disclosure of which is hereby expressly incorporated by reference.

Referring to FIG. 6, the subject disclosure provides a method 200, according to one embodiment of the subject disclosure, of making the three-dimensionally printed rib 36 (as a full rib 36A or half rib 36B) for the crash test dummy 12. For ease of description, the rib 36 formed includes the damping layer 46, although the same method generally could form a three-dimensionally printed rib 36 without a damping layer 46.

The method 200 starts in bubble 202 and advances to block 204. In block 204, the method 200 includes the step of providing a three-dimensional printer or printing system 110.

The method 200 advances to block 206 and includes the step of generating a CAD model of the rib 36. In one embodiment, a CAD model of the rib 36 was made to allow the 3D printer to print in one model.

In certain embodiments, the method makes a first CAD model of the rib 36 that forms the first rectangular cross-section RCL1 comprising the damping layer 46 sandwiched between the two band layers 40, 42 that extends along the axis A1 perpendicular to the first rectangular cross-section RCL1 to form the arcuate length AL1 terminated at the opposing ends 46A, 46B. Each of the opposing ends 46A, 46B forms the second rectangular cross-section RCL2 comprising the unitary band layer 40 and 42 without the damping layer 46 that extends away from the adjoined first rectangular cross-section damping layer 46 along the axis A1.

The method 200 advances to block 208 and includes the step of printing, by the three-dimensional printer or printing system 110, the rib 36 with at least two band layers 40, 42 of a band material and a layer 46 of damping material sandwiched in between the layers 40, 42 of the band material in one printing.

Accordingly, rib 36 and the rib cage assembly 16 of the subject disclosure has ribs 36 that are even more humanlike than in the past. Due to the advantage of the three-dimensional printing of two dissimilar materials in one printing, the ribs 36 can include hysteresis or damping that can be increased to make the ribs 36 more humanlike than ever before.

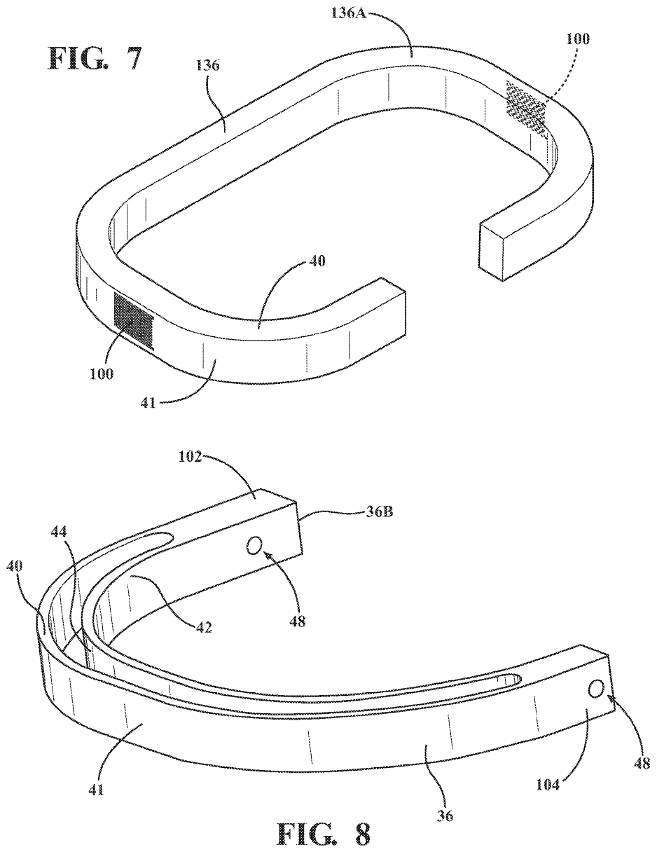

Referring next to FIGS. 7-12, exemplary embodiments of the modification of one of the ribs 36 of the rib cage assembly 16 is illustrated in FIGS. 3-4 to include one or more strain gauges 100 coupled thereto are provided, with the coupled strain gauges 100 thus transforming the ribs 36 of FIGS. 3-4 into the modified ribs 136 of FIGS. 7-12. In these embodiments, the modified ribs 136 may additionally labelled in the FIGS. 7-12 as a modified full rib 136A or a modified half rib 136B (in addition to being labelled as a full rib 36A or half rib 36B or simply a rib 36). Similar to the rib 36, the term “modified rib 136” specifically encompasses “a modified full rib 136A” or “a modified half rib 136B”.

In the embodiment of FIG. 7, a modified full rib 136A is illustrated which substantially corresponds to the shape of the embodiments of the full ribs 36A illustrated in FIGS. 3-4 but does not illustrate the apertures 48 that extend therethrough to allow for the introduction of fasteners for connection of the unmodified full rib 36 of the rib cage assembly 16 to the crash test dummy 12. In FIG. 7, a pair of strain gauges 100 are included (one visible and one in phantom) that have been printed (i.e., three-dimensionally printed) onto the outer surface 41 of the front band layer 40 of band material of the full rib 36A to form the modified full rib 136A. However, the electronic componentry used to electrically couple the strain gauges 100 to a controller 199, which is used to evaluate the strain occurring on the modified full rib 136A during a crash test simulation, is omitted. In FIG. 7, the rib 36 is three-dimensionally printed as a single band 40 of material but is also representative of a rib 36 having a pair of band layers 40, 42 without a damping layer 46.

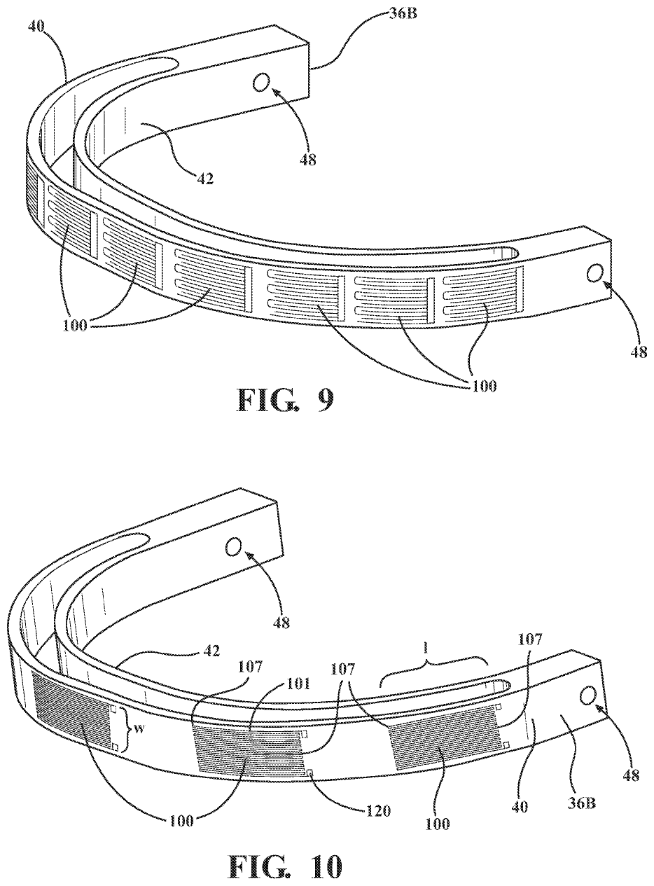

In the embodiment of FIG. 8, one rib 36 is illustrated as a half rib 36B that is configured for connection within the rib cage assembly 16 to the crash test dummy 12 with the half rib 36B corresponding to either the right side or the left side of the crash test dummy 12. In FIG. 9, the half rib 36B of FIG. 8 has been modified to include one or more three-dimensionally printed strain gauges 100 that have been printed (i.e., three-dimensionally printed) onto the outer surface 41 of the front band layer 40 of band material to form the modified half rib 136B.

In the embodiments of FIGS. 8-10, apertures 48 at either end of the half ribs 36B, 136B are included that extend therethrough to allow for the introduction of fasteners for connection of the half ribs 36B, 136B of the rib cage assembly 16 to the crash test dummy 12 corresponding to either the right side or the left side of the crash test dummy 12. Moreover, in the embodiments of FIGS. 10-12, the half ribs 36B, 136B are provided as including the front band layer 40 and rear band layer 42 with an interior 44 spaced therebetween that is not filled with the damping material 46, although in alternative embodiments could be filled with the damping material to form a damping layer 46 as described above.

The length l and width w of each of the respective strain gauges 100 (shown on FIG. 10) is determined based in part upon the length and width of rib 36 to which the strain gauge 100 is applied in conjunction with the desired area of the modified rib 136 in which strain will be measured during a crash test simulation. In this way, a measurement can be obtained of the actual strain level in a desired area of the underlying unmodified rib 36 covered with the strain gauge 100 instantaneously for a particular crash simulation, with the actual strain level more closely simulating the performance of an actual human rib under the same crash test simulation conditions. Still further, because the modified rib 136 includes three-dimensionally printed components (i.e., the underlying three-dimensionally printed rib 36 and the three-dimensionally printed strain gauge 100), the strain of the modified rib 136 can be measured in repeated crash test simulations.

In the embodiments of FIGS. 9-12, the modified half rib 136B is shown including a plurality of strain gauges 100 printed onto the outer surface 41 of the front band layer 40 of band material with FIGS. 10-12 also illustrating the introduction of a pair of solder joints 120 electrically connected at either end (i.e., a first end 103 and a second end 105) of each respective one of the printed strain gauges 100.

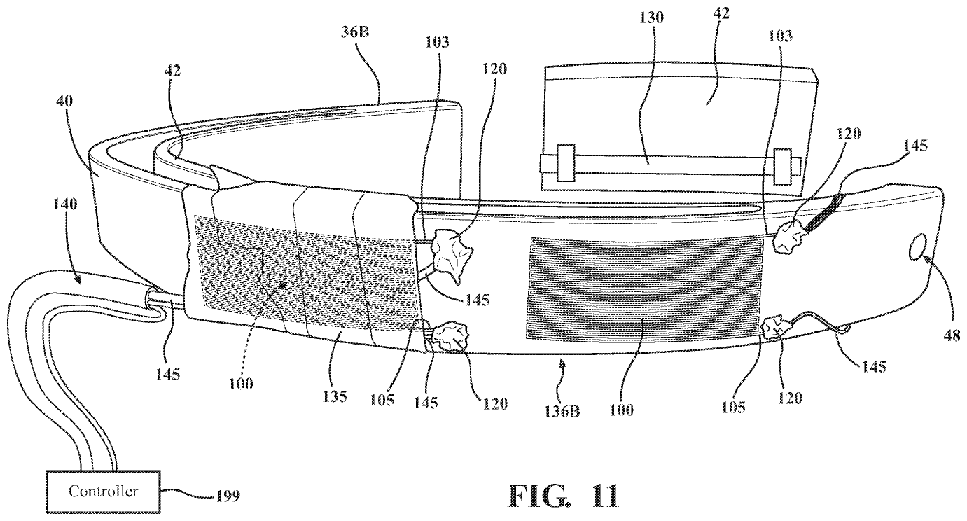

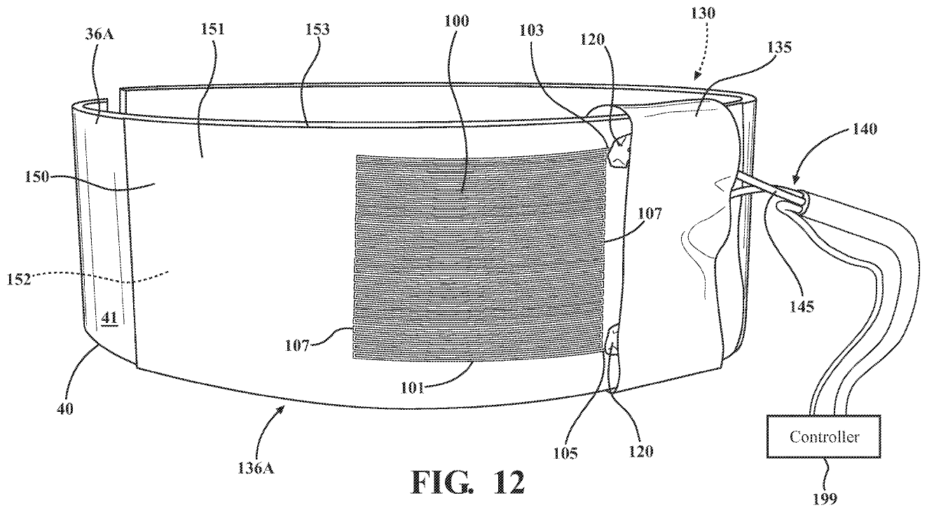

In addition, FIGS. 11 and 12 also illustrate the coupling of a wiring harness 140 (a portion of the wiring harness 140 is shown in FIGS. 11 and 12) along the outer surface 41 of the front band layer 40 with the ends of the wires 145 electrically connected to a respective solder joint 120. In certain embodiments, as also shown in FIG. 11, an adhesive tape 135 is positioned over a portion of the wiring harness 140 (and also optionally over the strain gauge 100 as also illustrated in FIG. 11) to couple the wiring harness 140 along the outer surface 41 of the front band layer outwardly relative to the respective strain gauge 100. The wires 145 of the wiring harness 140 are configured for coupling to the controller 199 at the respective wire ends opposite the ends connected to the solder joints 120. FIG. 11 also illustrates a second set of wires 145 extending from a second strain gauge 100 but omits the wiring harness 140 and its connection to the controller 199.

Still further, FIG. 11 illustrates a bolt 130 positioned adjacent to the rear band layer 42 that is used to couple the respective modified half rib 136B of the rib cage assembly 16 to the crash test dummy 12.

Even still further, in FIGS. 8-11, the ribs 36 are formed with the pair of band layers 40, 42 but without a damping layer 46, and thus the band layers 40, 42 defines a cavity between the opposing ends 46A, 46B corresponding to the first rectangular cross-section RCL1 (RCL1 is shown in FIG. 3 with the damping layer 46 present).

In yet another embodiment of the subject invention, one or more strain gauges 100 may be coupled to an outer surface of the three-dimensionally printed rib 36 via a polymeric sheet 150 to form a modified rib 136.

In one exemplary embodiment as shown in FIG. 12, a strain gauge 100 is three-dimensionally printed onto a front surface 151 of a polymeric sheet 150 that is coupled to a respective unmodified full rib 36A to form a modified half rib 136A. The polymeric sheet 150 has an adhesive backing (shown in phantom as 152) bonded onto its rear surface 153 opposite the front surface 151. The adhesive backing 152 is bonded onto the outer surface 41 of the front band layer 40 of band material of each of the rib 36 (FIG. 12 illustrates a rib 36, 36A without a single band layer 42 and without a damping layer 46. FIG. 12 also illustrates the introduction of a pair of solder joints 120 electrically connected at either end of a respective one of the printed strain gauges 100. In certain embodiments, the polymeric sheet 150 is a polyester film such as Mylar®.

In addition, FIG. 12 illustrates the coupling of a wiring harness 140 adjacent to the outer surface 41 of the front band layer 40 with the ends of the wires 145 electrically connected to a respective solder joint 120. In particular, an adhesive tape 135 is positioned over a portion of the wiring harness 140 to couple the wiring harness 140 along the outer surface 41 of the front band layer 40 outwardly relative to the respective strain gauge 100 and polymeric sheet 150. The wires 145 of the wiring harness 140 are configured for coupling to the controller 199.

In each of the respective embodiments of FIGS. 7-12, the strain gauge 100 defines an integrated sensor with the strain gauge 100 formed to include equally spaced rows 101 of an electrically conductive material applied to either the outer surface of the rib 36 directly or to the sheet 150, as described above, that are electrically connected in a serpentine configuration between the first end 103 and the second end 105. Accordingly, a series of ninety-degree bends 107 connect each adjacent row 101 (see FIG. 10) between the first and second ends 103, 105. The thickness of each of the rows 101 and bends 107 is sufficient to provide uniform electrical conductivity between the first and second ends 103, 105. The spacing between the parallel rows 101 is sufficient to prevent electrical connection of the rows between the bends 107.

In this serpentine configuration, and as also illustrated in FIG. 10, the length l of a respective strain gauge 100 is defined as the distance between bends 107 connecting adjacent rows 100, while the width w of the respective strain gauge 100 is defined as the distance between the two raised spaced furthest apart in a direction normal to the length.

In exemplary embodiments, the strain gauge 100 is applied directly onto the outer surface of the rib 36 or is applied to the rib 36 via the polymeric sheet 150, using a three-dimensional printing technique similar to the three-dimensional printing technique for forming the modified ribs 136 described above.

As noted above, the strain gauge 100 is formed from an electrically conductive material that can be applied via a three-dimensional printer or printing system similar to the three-dimensional printer or printing system 110 generally described above and illustrated in FIG. 7. In particular, three-dimensional printers that are able to apply the conductive materials to form the strain gauges 100 in the rows 101 with bends 107 as described above are preferred and include three-dimensional printers commercially available from nScrypt's 3Dn Series printers from nScrypt, Inc. of Orlando, Florida.

In certain embodiments, the electrically conductive material has a viscosity ranging from 1 centipoise to over 1 million centipoise. The electrically conductive material preferably includes conductive particles such as silver dispersed in a polymeric material or may be in the form of a nanoparticle silver ink that can be applied generally utilizing the techniques described in FIG. 8 above but modified to correspond to the printing of conductive materials according to the procedures from nScrypt's 3Dn Series printers. The thickness of the rows 101 and bends 107 should be sufficient to allow an electric charge to pass through the rows 101 and bends 107 of the strain gauge 100 between the first and second ends 103, 105.

In the embodiments in which strain gauge 100 is printed onto the outer surface of the curved component (i.e., the rib 36), such as in FIGS. 7, 9, 10 and 11, the component is held in place in a desired orientation by the three-dimensional printer or printing system 110 prior to the three-dimensional printing process described in FIG. 6 being initiated to print the strain gauge 100. In the embodiment of FIG. 12, the polymeric sheet 150 is positioned onto the base of the three-dimensional printer or printing system 110 and held in place prior to the three-dimensional printing process described in FIG. 6 to print the strain gauge 100.

In each of the embodiments, and once the strain gauges 100 applied to the rib 36 to form the modified ribs 136 are electrically coupled to the controller 199 via a respective wiring harness 140 with the strain gauges defining the integrated sensor, the crash test dummy 12 may be evaluated in a crash test simulation to determine performance characteristics of the component that closely correspond to the performance of the corresponding component of a human under similar crash circumstances. In particular, the controller 199 could measure the displacement of the respective modified rib 136 in lateral and frontal directions during this crash simulation that lasts between 10 and 200 milliseconds by measuring the changes in electrical signal from the strain gauges 100. The acquired data for the component, such as the rib 36, could then be utilized to optimize the component relative to a human component and then be used to optimize safety systems in vehicles in an attempt to minimize injury to humans during resulting in crashes.

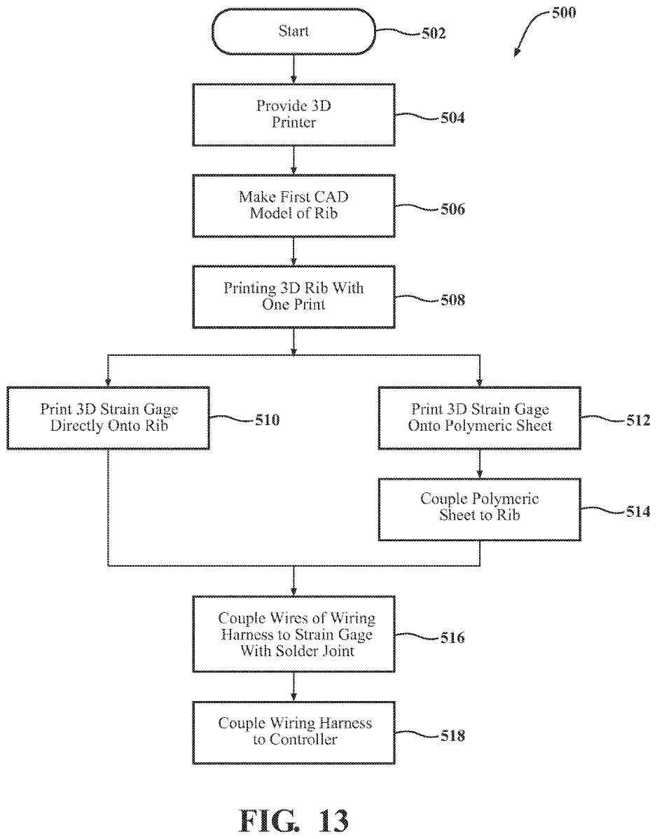

Referring to FIG. 13, the subject disclosure provides a method 500, according to various embodiments of the subject disclosure, of building upon the making the three-dimensionally printed modified rib 136 for the crash test dummy 12 to include the steps of coupling the electrical componentry to the strain gauge 100 such that the formed modified rib 136 with the strain gauge 100 is available for repeatable testing in crash test simulations, which will be described in FIG. 16 below.

The method 500 starts in bubble 502 and advances to block 504. In block 504, which corresponds to block 204 of FIG. 6, the method 500 includes the step of providing a three-dimensional printer or printing system 110. The method 500 advances to block 506, which corresponds to block 206 in FIG. 6, and includes the step of generating a first CAD model of the rib 36. In one embodiment, the first CAD model of the rib 36 was made to allow the 3D printer to print in one model. The method 500 advances to block 508, which corresponds to block 208 in FIG. 8, and includes the step of printing, by the three-dimensional printer or printing system 110, the rib 36 with at least two band layers 40, 42 of a band material and a layer 46 of damping material (i.e., a damping layer 46) sandwiched in between the layers 40, 42 of the band material in one printing. In certain alternative embodiments, the rib 36 is formed without the damping layer 46.

Next, the method 500 proceeds either to block 510 or to block 512.

In block 510, the method 500 proceeds and includes the step of printing, by the three-dimensional printer using a three-dimensional printing technique, the strain gauge 100 directly onto the outer surface of the rib 36 in a desired pattern and having a desired overall width and length to form the modified rib 136 having the strain gauge defining the integrated sensor. In certain embodiments, the three-dimensional printer used in block 510 is commercially available from nScrypt's 3Dn Series printers from nScrypt, Inc. of Orlando, Florida. In certain embodiments, the strain gauge 100 is directly printed onto the outer surface of either the first band layer 40 or second band layer 42 of the rib 36.

As an initial part of the step of block 510, a user determines the location along the interior or exterior of the rib 36 such as a particular location along either the first band layer 40 or second band layer 42 of the rib 36.

In particular, the electrically conductive material is applied onto the outer surface of the rib 36 (or onto the outer surface of either the first band layer 40 or second band layer 42 of the rib 36) via a three-dimensional printer or printing system similar to the three-dimensional printer or printing system 110 generally described above and illustrated in FIG. 7.

As a part of the step of block 510, the rib 36 is held in place in a desired orientation by the three-dimensional printer or printing system 110 prior to the three-dimensional printing process described in FIG. 8 being initiated to print the strain gauge 100.

In certain embodiments, the step of printing the strain gauge 100 in step 510 occurs continuously with the step of printing the three-dimensionally printed rib 36 of step 508. In particular, the strain gauge 100 may be printed onto a portion of the rib 36 already formed in step 508 but prior to the completion of step 508, wherein other portions of the rib 36 may be three-dimensionally printed after the three-dimensionally printing of some or all of the strain gauge 100. In other words, steps 508 and 510 may be done in a coordinated manner to three-dimensionally print both the rib 36 and strain gauge 100 continuously.

In other embodiments, the step of printing the strain gauge 100 in step 510 occurs after the step of printing the three-dimensionally printed rib 36 of step 508.

In the embodiment of FIG. 7-11, the rib 36 is held in place prior to the three-dimensional printing process described in block 510 to print the strain gauge 100 onto the front outer surface 41 of the rib 36. Once completed, the printed strain gauge 100 defines a sensor.

In block 512, in embodiments where the strain gauge 100 is applied to the rib 36 via the polymeric sheet 150, the method 500 proceeds and includes the step of printing, by the three-dimensional printer using a three-dimensional printing technique, the strain gauge 100 directly onto a front surface 151 of the polymeric sheet 150 (i.e., a first surface 151) using a three-dimensional printing technique.

The polymeric sheet 150 may include an adhesive previously applied onto opposing rear surface 153 (i.e., a second surface 153) of the polymeric sheet 150, or the method may proceed to block 514, wherein the adhesive backing 152 is applied to the second surface 153 of the polymeric sheet 150.

In the embodiment of FIG. 12, the polymeric sheet 150 is positioned onto the base of the three-dimensional printer or printing system 110 and held in place prior to the three-dimensional printing process described in FIG. 6 to print the strain gauge 100 onto the front surface 151 of the polymeric sheet 150. Once completed, the printed strain gauge 100 defines a sensor.

In block 514, the polymeric sheet 150 is coupled to the surface of the rib 36 to form the modified rib 136. In particular, the adhesive backing 152 is pressed into adhering contact with the surface of the rib 36 such that the adhesive backing 152 is positioned between the strain gauge 100 and the surface of the rib 36.

In certain embodiments, the adhesive backing 152 is pressed into adhering contact with the surface of one of the band layers 40, 42 of the rib 36 at a desired location such that the adhesive backing 152 is positioned between the strain gauge 100 and the surface of the rib 36 to form the modified rib 136.

Next, in step 516, the wires 145 of a wiring harness 140 are electrically coupled to the respective ends 103, 105 of the strain gauges 100 coupled to the rib 36.

Finally, in step 518, the wires 145 of the wiring harness are electrically coupled to the controller 199, and the modified rib 136 is therefore ready for use in a crash test simulation.

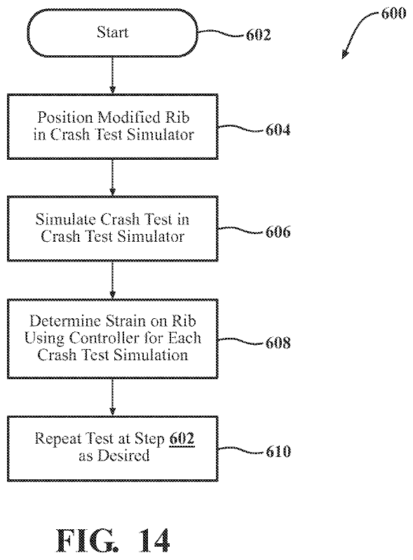

Referring now to FIG. 14, an associated method 600 of evaluating the modified rib 136 formed according to FIG. 13 is provided.

The method 600 starts in bubble 602 and advances to block 604. In block 604, the modified rib 136, prepared according to the method of FIG. 13 to include wherein the wires 145 of a wiring harness 140 are electrically coupled between the controller 199 and the strain gauges 100, and preferably coupled to the crash test dummy 12, is positioned in a desired location of a crash test simulator.

Next, as illustrated in block 606, the crash test dummy 12 then undergoes a sudden impact causing strain in the integrated sensor/strain gauge 100, corresponding to a location on the three-dimensionally printed rib 36, in a very short time span (i.e., the time of an impact simulation), and in particular a time span 10 to 200 milliseconds, such as 50 milliseconds at forces exceeding 7000 N or 60 milliseconds at forces exceeding 3500 N. The deformation causes strain on the strain gauge 100 resulting in areas that are stretched and others that are compressed. Further, the rib 136 and strain gauge 100 undergoes repeated deformations. The strain on the integrated sensor/strain gauge 100 (in terms of the stretching and compression) causes an electrical signal change in the strain gauge 100 that is sensed by the controller 199 with the electrical signal being sent from the strain gauge 100, through the solder joints 102, and through the wires 145 of the wiring harness 140 to the controller 199.

Next, as illustrated in block 608, the controller 199 utilizes a computer program and various algorithms contained in the computer program to interpret the change in electrical signal from the strain gauges 100 occurring during the 10 to 200 milliseconds of a crash test simulation to determine the strain on the rib 36 corresponding in location to the strain gauge 100 during each 10 to 200 milliseconds time period of crash test simulation.

Notably, and owing to the use of three-dimensionally printed ribs 36 and strain gauges 100, the same modified rib 136 can be repeatedly tested or otherwise evaluated under the same or different crash test conditions to determine the repeated impacts corresponding to the ribs of a human as illustrated in block 610.

The subject disclosure has been described in an illustrative manner. It is to be understood that the terminology, which has been used, is intended to be in the nature of words of description rather than of limitation.

Many modifications and variations of the subject disclosure are possible in light of the above teachings. Therefore, the subject disclosure may be practiced other than as specifically described.

1. A method of making a three-dimensionally printed rib and a three-dimensionally printed strain gauge for a crash test dummy, said method comprising the steps of:
providing a three-dimensional printer;
generating a first CAD model of the three-dimensionally printed rib for the crash test dummy;
generating a second CAD model of the three-dimensionally printed strain gauge for the crash test dummy;
printing, by the three-dimensional printer based on the first CAD model, the three-dimensionally printed rib formed of a polymeric material having an outer surface; and
printing, by the three-dimensional printer based on the second CAD model, the three-dimensionally printed strain gauge formed of a conductive metallic ink directly onto the outer surface of the three-dimensionally printed rib to define an integrated sensor on the three-dimensionally printed rib such that the integrated sensor detects strain in the three-dimensionally printed rib during a collision test where the three-dimensionally printed rib undergoes a sudden impact causing strain in the integrated sensor in a time span from 10 to 200 milliseconds.

2. The method of claim 1, wherein the step of printing, by the three-dimensional printer based on the first CAD model, the three-dimensionally printed rib formed of a polymeric material having an outer surface comprises:
generating a first CAD model of the three-dimensionally printed rib for the crash test dummy, wherein the first CAD model of the three-dimensionally printed rib forms a first rectangular cross section comprising a damping layer sandwiched between two band layers, the first rectangular cross section extends along an axis perpendicular to the first rectangular cross section to form an arcuate length terminated at opposing ends, and each of the opposing ends forms a second rectangular cross section comprising a unitary band layer without a damping layer that extends away from the first rectangular cross section damping layer along the axis; and
printing, by the three-dimensional printer, the first CAD model using a band material to form the band layers and a damping material to form the damping layer with the band layers having an outer surface.

3. The method of claim 2, wherein the step of printing, by the three-dimensional printer based on the second CAD model, the three-dimensional strain gauge onto a surface of the three-dimensional component comprises:
printing, by the three-dimensional printer based on the second CAD model, the three-dimensional strain gauge formed of a conductive metallic ink directly onto the outer surface of one of the two band layers to define an integrated sensor on the three-dimensionally printed rib such that the three-dimensionally printed rib with the integrated sensor detects strain in the three-dimensionally printed rib during a collision test where the three-dimensionally printed rib undergoes a sudden impact causing strain in the integrated sensor in a time span from 10 to 200 milliseconds.

4. The method of claim 1, wherein the step of printing, by the three-dimensional printer based on the first CAD model, the three-dimensionally printed rib formed of a polymeric material having an outer surface comprises:
generating a first CAD model of the three-dimensionally printed rib for the crash test dummy, wherein the first CAD model of the three-dimensionally printed rib forms a first rectangular cross section comprising two band layers defining a cavity therebetween, the first rectangular cross section extends along an axis perpendicular to the first rectangular cross section to form an arcuate length terminated at opposing ends, and each of the opposing ends forms a second rectangular cross section comprising a unitary band layer without the cavity that extends away from the first rectangular cross section damping layer along the axis; and
printing, by the three-dimensional printer, the first CAD model using a band material to form the band layers with the band layers having an outer surface.

5. The method of claim 4, wherein the step of printing, by the three-dimensional printer based on the second CAD model, the three-dimensional strain gauge onto a surface of the three-dimensional component comprises:
printing, by the three-dimensional printer based on the second CAD model, the three-dimensional strain gauge formed of a conductive metallic ink directly onto the outer surface of one of the two band layers to define an integrated sensor on the three-dimensionally printed rib such that the three-dimensionally printed rib with the integrated sensor detects strain in the three-dimensionally printed rib during a collision test where the three-dimensionally printed rib undergoes a sudden impact causing strain in the integrated sensor in a time span from 10 to 200 milliseconds.

6. The method of claim 1, wherein said step of printing the three-dimensional strain gauge is performed continuously with said step of printing the three-dimensionally printed rib.

7. A crash test dummy comprising:
a body;
a spine assembly operatively attached to said body;
a rib cage assembly coupled to said spine assembly having a plurality of three-dimensionally printed ribs formed of a polymeric material each having an outer surface; and
a three-dimensionally printed strain gauge formed of a conductive metallic ink directly onto said outer surface on one three-dimensionally printed rib of said plurality of three-dimensionally printed ribs to define an integrated sensor on said one three-dimensionally printed rib with said three-dimensionally printed strain gauge configured for detecting strain in said one three-dimensionally printed rib where said one three-dimensionally printed rib undergoes a sudden impact in a time span from 10 to 200 milliseconds.

8. The crash test dummy of claim 7, wherein said at least one three-dimensionally printed rib forms a first rectangular cross section comprising a damping layer sandwiched between two band layers, the first rectangular cross section extending along an axis perpendicular to the first rectangular cross section to form an arcuate length terminated at opposing ends, and each of the opposing ends forming a second rectangular cross section comprising a unitary band layer without a damping layer that extends away from the first rectangular cross section damping layer along the axis.

9. The crash test dummy of claim 7, wherein said at least one three-dimensionally printed rib forms a first rectangular cross section comprising two band layers defining a cavity therebetween, the first rectangular cross section extending along an axis perpendicular to the first rectangular cross section to form an arcuate length terminated at opposing ends, and each of the opposing ends forming a second rectangular cross section comprising a unitary band layer without the cavity that extends away from the first rectangular cross section damping layer along the axis.

10. The crash test dummy according to claim 7 further comprising:
a controller; and
a wiring harness including one or more wires electrically coupling said three-dimensionally printed strain gauge to said controller,
said controller configured for determining a change in an amount of strain of said three-dimensionally printed rib through a corresponding change in said three-dimensionally printed strain gauge where said three-dimensionally printed component undergoes said sudden impact in said time span from 10 to 200 milliseconds.

11. The crash test dummy of claim 10 further comprising a solder joint for electrically coupling said three-dimensionally printed strain gauge to said one or more wires.

12. A system for forming a three-dimensionally printed component having a three-dimensionally printed strain gauge coupled thereto for a crash test dummy, the system comprising:
a three-dimensional printer; and
a controller coupled to the three-dimensional printer and configured to:
generate a first CAD model of the three-dimensionally printed component for the crash test dummy;
generate a second CAD model of the three-dimensionally printed strain gauge for the crash test dummy;
print, by the three-dimensional printer based on the first CAD model, the three-dimensionally printed component formed of a polymeric material having an outer surface; and
print, by the three-dimensional printer based on the second CAD model, the three-dimensionally printed strain gauge formed of a conductive metallic ink directly onto the outer surface of the three-dimensionally printed component to define an integrated sensor on the three-dimensionally printed component such that the integrated sensor detects strain in the three-dimensionally printed component during a collision test where the three-dimensionally printed component undergoes a sudden impact causing strain in the integrated sensor in a time span from 10 to 200 milliseconds.

13. The system of claim 12, wherein the three-dimensionally printed component comprises a three-dimensionally printed rib,
wherein the controller of the system is configured to:
generate the first CAD model of the three-dimensionally printed rib for the crash test dummy, wherein the first CAD model of the three-dimensionally printed rib forms a first rectangular cross section comprising a damping layer sandwiched between two band layers, the first rectangular cross section extends along an axis perpendicular to the first rectangular cross section to form an arcuate length terminated at opposing ends, and each of the opposing ends forms a second rectangular cross section comprising a unitary band layer without a damping layer that extends away from the first rectangular cross section damping layer along the axis; and
print, by the three-dimensional printer based on the first CAD model, the three-dimensionally printed rib formed of a polymeric material having an outer surface.

14. The system of claim 12, wherein the three-dimensionally printed component comprises a three-dimensionally printed rib,
wherein the controller of the system is configured to:
generate the first CAD model of the three-dimensionally printed rib for the crash test dummy, wherein the first CAD model of the three-dimensionally printed rib forms a first rectangular cross section comprising two band layers defining a cavity therebetween, the first rectangular cross section extending along an axis perpendicular to the first rectangular cross section to form an arcuate length terminated at opposing ends, and each of the opposing ends forming a second rectangular cross section comprising a unitary band layer without the cavity that extends away from the first rectangular cross section damping layer along the axis; and
print, by the three-dimensional printer based on the first CAD model, the three-dimensionally printed rib formed of a polymeric material having an outer surface.

15. A system for making a three-dimensional component having a strain gauge coupled thereto for a crash test dummy, the three-dimensionally printed strain gauge configured for detecting strain in the three-dimensionally printed component during a collision test where the three-dimensionally printed component undergoes a sudden impact causing strain in the three-dimensionally printed component in a time span from 10 to 200 milliseconds, the system comprising:
a three-dimensional printer; and
a controller coupled to the three-dimensional printer and configured to:
generate a first CAD model of the three-dimensional component for the crash test dummy;
generate a second CAD model of the three-dimensional strain gauge for the crash test dummy;
print, by the three-dimensional printer, the first CAD model of the three-dimensional component;
providing a polymeric sheet having a front surface and an opposing rear surface; and
print, by the three-dimensional printer, the second CAD model of the three-dimensional strain gauge onto the front surface of the polymeric sheet;
wherein the polymeric sheet is subsequently coupled to the three-dimensional component such that the polymeric sheet is disposed between the three-dimensional component and the three-dimensional strain gauge.

16. The system of claim 15, wherein the three-dimensionally printed component comprises a three-dimensionally printed rib,
wherein the controller of the system is configured to:
generate the first CAD model of the three-dimensionally printed rib for the crash test dummy, wherein the first CAD model of the three-dimensionally printed rib forms a first rectangular cross section comprising a damping layer sandwiched between two band layers, the first rectangular cross section extends along an axis perpendicular to the first rectangular cross section to form an arcuate length terminated at opposing ends, and each of the opposing ends forms a second rectangular cross section comprising a unitary band layer without a damping layer that extends away from the first rectangular cross section damping layer along the axis; and
print, by the three-dimensional printer based on the first CAD model, the three-dimensionally printed component formed of a polymeric material having an outer surface.

17. The system of claim 15, wherein the three-dimensionally printed component comprises a three-dimensionally printed rib,
wherein the controller of the system is configured to:
generate the first CAD model of the three-dimensionally printed rib for the crash test dummy, wherein the first CAD model of the three-dimensionally printed rib forms a first rectangular cross section comprising two band layers defining a cavity therebetween, the first rectangular cross section extending along an axis perpendicular to the first rectangular cross section to form an arcuate length terminated at opposing ends, and each of the opposing ends forming a second rectangular cross section comprising a unitary band layer without the cavity that extends away from the first rectangular cross section damping layer along the axis; and
print, by the three-dimensional printer based on the first CAD model, the three-dimensionally printed rib formed of a polymeric material having an outer surface.
